(19) United States
(12) Patent Application Publication
(10) Pub. No.: US 2018/0029544 A1
(43) Pub. Date: Feb. 1, 2018

(54) ROOF SUPPORT STRUCTURE FOR SOLAR PANEL MODULE

(71) Applicant: Ford Global Technologies, LLC, Dearborn, MI (US)

(72) Inventors: Adrian NANIA, Rochester, MI (US); Jacob MATHEWS, Canton, MI (US); Noah Barlow MASS, Ypsilanti, MI (US); Daniel BOSTON, Dearborn, MI (US); Hadi MALEK, Dearborn, MI (US); Michael Robert TINSKEY, Commerce, MI (US)

(21) Appl. No.: 15/219,600

(22) Filed: Jul. 26, 2016

(51) Int. Cl. B60R 16/033; H01L 31/0216; H01L 31/024; H02J 7/35; B60R 11/00; B60R 13/06; B60R 13/08; H02S 20/30; B60J 7/043

(52) U.S. Cl. CPC B60R 16/033; H02S 20/30; H01L 31/02167; H01L 31/024; B60J 7/043; B60R 11/00; B60R 13/06; B60R 13/0869; H02J 7/355; B60R 2011/004; B60R 2011/0045; B60R 2011/0084

(57) ABSTRACT

A support structure for a vehicle roof panel includes a solar panel module. The solar panel module is disposed within an opening defined by an outer periphery of a support structure. The solar panel module includes a first part configured to slide underneath a second part containing a solar array adhered to a flange. The flange has a plurality of ribs extending across the solar array. The ribs have a V-shaped cross-section to support the solar panel module within the second part.

### TECHNICAL FIELD

This disclosure relates to a roof support structure for solar panels attached to a vehicle roof panel.

### BACKGROUND

Certain vehicles may be equipped with a sunroof or moon roof. These additional features require adaptation and attachment to the roof panel.

### SUMMARY

A vehicle includes a roof panel defining an opening, a support structure and a solar panel module. The support structure is attached to the roof panel and disposed within the opening. The support structure includes first and second sections, at least two leg portions, and a divider disposed between the leg portions and separating the first and second sections. The first section is defined between the leg portions and the divider, and the second section is defined between the leg portions and the divider disposed adjacent the first section. The solar panel module is disposed within the first or second section. The solar panel module includes a solar array adhered, via an electrical discharge film, to a plate having a plurality of ribs extending over an area of the solar array. The ribs have a V-shaped cross-section spaced throughout the area to support the solar panel module within the support structure.

A vehicle roof panel includes a support structure and a solar panel module. The support structure has a first section defined by an outer periphery of the support structure. The solar panel module is disposed within the first section, and includes a solar array adhered to a plate having a plurality of ribs extending over an area of the solar array. The ribs have a V-shaped cross-section spaced throughout the first section to support the solar panel module within the support structure.

A support structure for a vehicle roof panel includes a solar panel module. The solar panel module is disposed within an opening defined by an outer periphery of a support structure. The solar panel module includes a first part configured to slide underneath a second part containing a solar array adhered to a plate. The plate has a plurality of ribs extending across the solar array. The ribs have a V-shaped cross-section to support the solar panel module within the second part.

### BRIEF DESCRIPTION OF THE DRAWINGS

FIG. 1 is a perspective view of a vehicle with a solar panel module on a roof panel;

FIG. 2 is a perspective view of the vehicle roof panel and a support structure to support a moon roof and the solar panel module;

FIG. 3 is a cross-sectional view taken along the lines 2-2 of FIG. 2 of the support panel module; and

FIG. 4 is a cross-sectional view taken along the lines 2-2 of FIG. 2 of a further embodiment of the solar panel module.

### DETAILED DESCRIPTION

Embodiments of the present disclosure are described herein. It is to be understood, however, that the disclosed embodiments are merely examples and other embodiments may take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

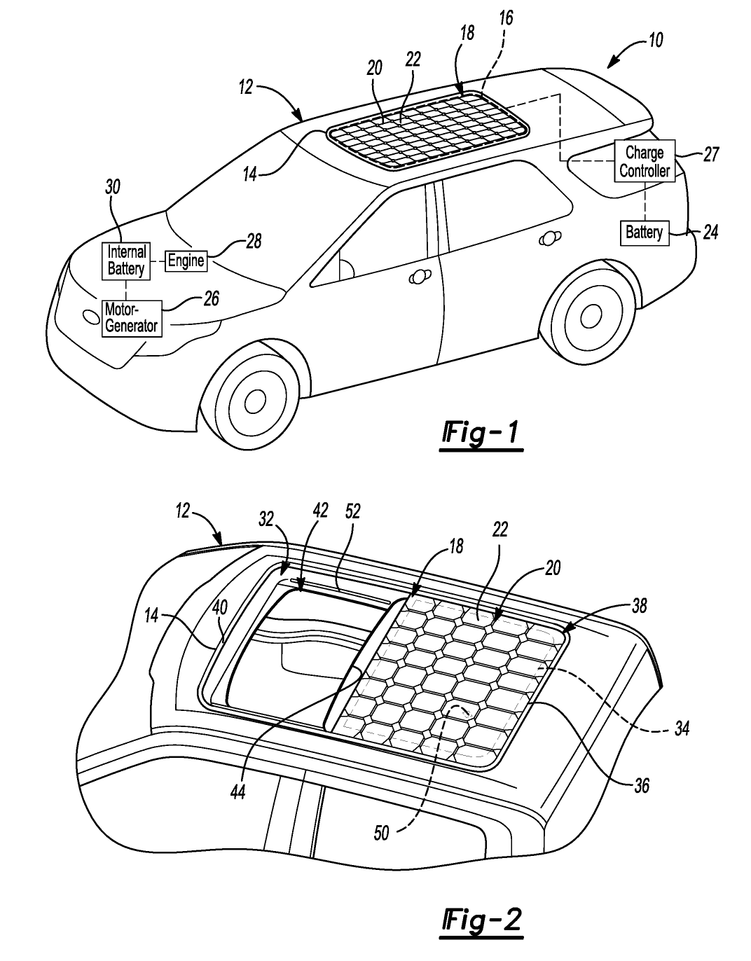

FIG. 1 depicts a perspective view of a vehicle 10 having a roof panel 12 defining an opening 14. The vehicle 10 also includes a support structure 16 disposed within the opening 14 attached to the roof panel 12 and a solar panel module 18. The solar panel module 18 attaches to the roof panel 12 via the support structure 16. The solar panel module 18 comprises a solar array 20. The solar array 20 is configured to convert radiation energy into electrical energy for use with the vehicle 10. The solar array 20 uses a plurality of solar cells 22 connected in series to convert radiation energy into electrical energy for the vehicle 10. For example, the solar panel module 18 via the solar array 20 can be used as an accessory power source for charging a battery 24 within the vehicle 10 using a charge controller 27. The battery 24 may include any device capable of storing charge from the solar panel module 18 such as, but not limited to, lithium-ion batteries, nickel cadmium batteries, nickel metal hydride batteries, lead acid batteries, or lithium polymer batteries. The battery 24 may also include a single battery 24, or multiple batteries 24 configured to power tools, laptops, air compressors, lights, or any other instrument or device commonly used by passengers within the vehicle 10.

Powering accessory devices within the vehicle 10 results in poor fuel economy. For example, the vehicle 10 needs to run an engine 26 in order to provide power to various accessory devices within the vehicle 10 or used by the vehicle 10, such as lights, wipers, or E bikes. Providing power through the solar panel module 18 to the devices allows the vehicle 10 to increase fuel economy by further reducing combustion through the engine 26 by removing the need for the vehicle 10 to idle. Likewise, an internal battery 28 may be used to power other components within the vehicle 10, such as a motor generator 30. The solar panel module 18 allows the internal battery 28 of the vehicle to power the motor generator 30 for an extended time. When the vehicle 10 is being powered by the motor generator 30, combustion through the engine 26 is not required. Therefore, the solar panel module 18 may allow the vehicle 10 to have an extended range using the motor generator 30 and further improve fuel economy. The solar panel module 18 may also be configured to power the internal battery 28 in order to increase the travel time and range of the motor generator 30 for the vehicle 10.

As stated above, the solar panel module 18 attaches to the roof panel 12 through the support structure 16. During normal vehicle operation, the solar panel module 18 may be subject to torsional and bending loads. The support structure 16 allows the solar panel module 18 to be isolated away from direct loading as a result of normal vehicle operation. Isolation and the lack of direct loading on the solar panel module 18 is a result of the support structure 16 interconnecting the solar panel module 18 and the roof panel 12. The support structure acts 16 as an intermediary between the solar panel module 18 and the roof panel 12 to avoid direct loading on the solar cells 22 and improve efficiency of the solar array 20 during charging as described above. The support structure 16 may attach to the roof panel 12 through fastening and the solar panel module 18 attaches to the support structure 16 via bonding. In at least one other embodiment, the support structure 16 may attach to the roof panel through hemming, welding, or any other method to attach a support structure 16 within an opening 14 on the roof panel 12 and the solar panel module may be attached to the support structure 16 via fastening.

As shown in FIG. 1, the solar panel module 18 defines the solar array 20 across an entirety of the support structure 16 and likewise the opening 14. In at least one other embodiment, detailed with reference to FIG. 2, the solar array 20 of the solar panel module 18 may be disposed across a first section 32 of the support structure 16. The solar panel module 18 may further include a first part 34 and a second part 36. The first part 34 of the solar panel module 18 may be disposed across the first section 32 of the support structure 16 and the second part 36 of the solar panel module 18 may be disposed across a second section 38 of the support structure 16. The solar panel module 18 including the orientation, layout, and design of the solar array 20 may be optimized based on power consumption and need for the vehicle 10.

Referring to FIG. 2, a perspective view of the roof panel 12, the support structure 16 and the solar panel module 18 including the solar array 20 is depicted. FIG. 2 depicts the second part 36 of the solar panel module 18 disposed within the second section 38 of the support structure 16 and the first part 34 of the solar panel module 18 slid underneath the second part 36. The support structure 16 defines an outer periphery 40 within the opening 14 of the roof panel 12. The outer periphery 40 is bordered by at least two leg portions 42 and a divider 44. The divider 44 separates the first section 32 from the second section 38 and extends between the at least two leg portions 42. The first part 34 is defined between the first section 32 and the divider 44 and the second part 36 is defined between the second section 38 and the divider 44.

As described above, the solar panel module 18 may define a first part 34 disposed in a first section 32 of the support structure and a second part 36 disposed in a second section 38 of the support structure 16. In at least one other embodiment, the first part 34 may be disposed in the first section 32 of the support structure 16 and a windowpane 50 may be disposed in the second section 38 of the support structure 16. Likewise, the second part 36 may be disposed in the second section 38 of the support structure 16 and the windowpane 50 may be disposed in the first section 32 of the support structure 16. Placing the windowpane 50 in either the first or second sections 32, 38 of the support structure 16 allows the roof panel 12 to define a moon roof for the vehicle 10.

The support structure 16 they further include a track 52. The track 52 may be defined in line and adjacent the at least two leg portions 42. The track 52 allows the first part 34 of the solar panel module 18 to slide underneath the second part 36 of the solar panel module 18. Therefore, after sliding, the first part 34 may be disposed underneath the second part 36. When the first part 34 is disposed underneath the second part 36, the solar panel module 18 may be defined entirely within the second section 38 of the support structure 16. The track 52 may also allow the second part 36 of the solar panel module 18 to slide underneath the first part 34 such that the entire solar panel module 18 may be defined entirely within the first section 32 of the support structure 16.

If the windowpane 50 is disposed within the first or second sections 32, 38, the windowpane 50 may be configured to slide along the track 52 to define a sunroof within either the first or second sections 32, 38. For example, if the windowpane 50 is disposed within the first section 32 of the support structure 16, the second part 36 of the solar panel module 18 may be disposed in the second section 38 of the support structure 16 and the windowpane 50 may be configured to slide along the track 52 underneath the second part 36 of the solar panel module 18. Likewise, if the windowpane 50 is disposed within the second section 38 of the support structure 16, the first part 34 of the solar panel module 18 may be disposed within the first section 32 of the support structure 16 and the windowpane 50 may be configured to slide along the track 52 underneath the first part 34 of the solar panel module 18.

The windowpane 50 is configured to slide along the track 52 underneath either the first part 34 or the second part 36 of the solar panel module 18 for increased efficiency of the solar panel module 18. By sliding underneath the first or second parts 34, 36, the windowpane 50 avoids potential obstruction or distortion of the light absorption by the solar panel module 18 to increase the energy absorbed by the solar panel module 18. In at least one other embodiment, the windowpane 50 may be configured to slide along the track 52 to a position above either the first part 34 or the second part 36 of the solar panel module 18 if the windowpane 50 is disposed within the first section 32 or the second section 38 of the support structure 16, respectively. If the windowpane 50 is configured to slide above the solar panel module 18, the windowpane 50 may provide further protection to the solar panel module 18.

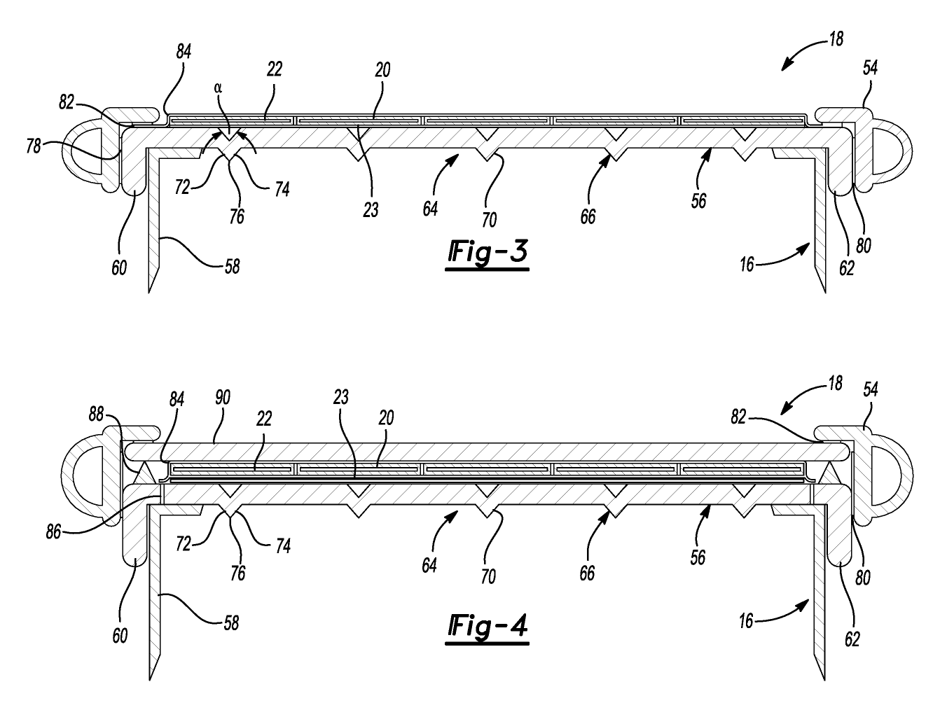

Referring to FIGS. 3 and 4, a cross-sectional view of the solar panel module 18 attached to the support structure 16 is shown. For example, the solar panel module 18 further includes a housing 54, a plate 56 and a bracket 58. FIG. 3 depicts a first embodiment of the solar panel module 18 and FIG. 4 depicts a second embodiment of the solar panel module 18. The first embodiment, shown in FIG. 3, allows the plurality of solar cells 22 to be exposed to radiation energy directly on the vehicle 10 whereas the second embodiment, shown in FIG. 4 covers the plurality of solar cells 22.

While shown and described as single and different embodiments, the solar panel module 18 may incorporate one or both of the first and second embodiments. For example, in the embodiment in which the solar panel module 18 has a first part 34 disposed in the first section 32 of the support structure 16 and the second part 36 is disposed in the second section 38 of the support structure 16, the first part 34 may include the embodiment shown and described in FIG. 3 and the second part 36 may include the embodiment shown and described in FIG. 4. Likewise, for example, the first and second parts 34, 36 of the solar panel module 18 may both include the embodiment shown in either of FIG. 3 or 4. Utilizing the embodiment shown in FIGS. 3 and 4, either individually or in combination, may depend on a variety of factors including, but not limited to, cost, weight and efficiency of the solar panel module 18.

Referring to FIG. 3, a cross-sectional view of the first embodiment of the solar panel module 18 is shown. As stated above, the solar panel module 18 includes a housing 54, a plate 56 and a bracket 58. The bracket 58 attaches to the plate 56. In at least one embodiment, the bracket 58 may be spot welded to the plate 56. In at least one other embodiment, the bracket 58 may be attached to the plate 56 using adhesive, fasteners, or any other attachment method. The bracket 58 attaches to the support structure 16 in order to maintain the solar panel module 18 and the first or second sections 32, 38 of the support structure 16, as described above. The bracket 58 allows a support structure 16 to support the solar panel module 18 on the roof 12 the vehicle 10.

The plate 56 is disposed between the bracket 58 and the housing 54 and supports the solar panel module 18. Specifically, the plate 56 is configured to support the solar array 20 including the plurality of solar cells 22. The solar array 20 is adhered to the plate 56 using an electrical discharge film 23. The plate 56 includes a first end 60 and a second and 62. The first end 60 is disposed opposite the second end 62, wherein the first and second ends 60, 62 are disposed across the solar array 20. Therefore, the plate 56 extends across and over an area 64 defined by the solar array 20 between the first and second ends 60, 62. The plate 56 may further include a plurality of ribs 66. The plurality of ribs 66 extends across the area 64 defined by the solar array 20 and is disposed underneath the solar array 20. The plurality of ribs 66 extends across the plate 56 between first and second ends 60, 62 and is centered on the solar cells 22 of the solar array 20.

Centering the ribs 66 on the solar cells 22 provides optimal support for the solar array 20 over the area 64 between the first and second ends 60, 62 of the plate 56. The plurality of ribs 66 provide added stiffness to the plate 56 to further support the solar array 20 of the solar panel module 18 within the support structure 16. The plurality of ribs 66 defines a substantially V-shaped cross-sectional area 68. For example, each rib 70 of the plurality of ribs 66 includes a first and second side 72, 74 that culminate in an apex 76 to form a V-shape. The V-shape of the ribs 66 provides the required stiffness and rigidity of the plate 56 over the area 64 defined by the solar array 20 between the first and second ends 60, 62. Further, the plurality of ribs 66 may be cross patterned across the plate 56. Cross patterning the ribs 66 across the area 64 between the first and second ends 60, 62 further aids the plate 56 to support the solar array 20 across the plate 56. As will be described in more detail below, the V-shape cross-sectional area 68 of the plurality of ribs 66 also aids to improve cooling of the solar cells 22. The apex 76 of the plurality of ribs 66 may be defined in a direction away from the solar array 20. Therefore, air flow may be directed under the plurality of solar cells 22 and away from the solar array 20 using the plurality of ribs 66. In at least one other embodiment, the plurality of ribs 66 may define a substantial U-shape, W-shape, or any other shape that allows the plate 56 be added support and stiffness for the solar array 20.

The apex 76, formed from the first and second sides 72, 74 includes an angle α. The size of the first and second sides, including the length of the sides 72, 74 may be optimized based on various vehicle characteristics, such as size, weight and stiffness required to support the solar panel module 18. Further, the angle a may also be optimized depending on the support required for optimal use of the solar panel module. For example, larger vehicles may require a larger and heavier solar panel module and the sides 72, 74 and the angle α of the plurality of ribs 66 may be designed to support a larger solar panel module 18 without impacting performance of the solar panel module 18. Likewise, small vehicles may require a smaller and lighter solar panel module 18 and the sides 72, 74 and the angle α of the plurality of ribs 66 may be designed to support a smaller solar panel module 18 without impacting performance of the solar panel module 18. Again, the sides 72, 74 and the angle α may be based on the packaging space available for the support structure 16 and solar panel module 18.

The first and second ends 60, 62 of the plate 56 may be turned down for added stiffness of the plate 56. For example, the first and second ends 60, 62 may be substantially perpendicular to the area 64 defined by the solar array 20 and substantially parallel to the bracket 58. The first and second ends 60, 62 may also be substantially parallel to the apex 76 of the plurality of ribs 66. Therefore, the first and second ends 60, 62 of the plate 56 provide further stiffness to the plate such that the solar array 20 extends across the area 64 in a substantially planar orientation. The plate 56 may be stamped aluminum and range in thickness from 0.8 millimeters to 1.2 millimeters. In at least one other embodiment, the plate 56 may be e-coated steel, or any other material configured to support the solar array 20 using the plurality of ribs 66, as described above.

Maintaining a substantially planar orientation of the solar array 20 ensures efficient absorption of radiation energy from the plurality of solar cells 22. For example, by eliminating sag within the plate 56, via the plurality of ribs 66, the solar array remains relatively flat across the plate 56 such that a maximum of the plurality of solar cells 22 remains substantially perpendicular to incident radiation for energy absorption. Further, absorption of radiation energy using the plurality of solar cells 22 may also cause the plurality of solar cells 22 to absorb heat. The plurality of ribs 66 and, therefore, the plate 56 may further aid to direct the heat flow away from the plurality of solar cells 22. For example, the plurality of ribs 66 may act as a plurality of cooling fins to pull heat due to incident radiation energy absorption from the solar cells 22 and direct the heat across the plate 56 to the first and second ends 60, 62, detailed below. The plurality of ribs 66 increase the surface area of the plate 56, which allows the plate 56 to be thinner improving the thermal conductivity through the plate and away from the solar array 20.

The housing 54 is configured to attach to the plate 56. The housing 54 further aids to seal the plate 56 as well as the solar array 20 to prevent moisture from corroding the plate 56 or damaging the solar array 20. The housing 54 is configured to surround the solar array 20 and includes a first seal 78 disposed at the first end 60 of the plate 56 and a second seal 80 disposed at the second end 62 of the plate 56. The first and second seals 78, 80 may be composed of rubber such that the first and second seals 78, 80 further aid to damp vibrations across the solar array 20 during normal vehicle operation. The first and second seals 78, 80 may be adhered to the housing 54 using a pressure sensitive tape 82. The pressure sensitive tape 82 ensures that the solar array 20 is properly sealed by the first and second seals 78, 80 without damaging the solar array 20. To account for moisture that may pool or may fall past the first or second seals 78, 80, the housing 54 may further include a water management system (not shown) typically used for moon roof frames. The water management system (not shown) may include troughs (not shown) to route the moisture to the first and second ends 60, 62 of the plate 56 and into drain tubes (not shown), which route and move the moisture back to the external environment and under the vehicle 10.

Further, the solar array 20 may be protected using a film 84. The film 84 may be a clear and protective film 84 to cover the plurality of solar cells 22 and protect plurality of solar cells 22 from damage due to weather, use or operation of the vehicle 10. The film 84 attaches to the housing 54 between the plate 56 and the first and second seals 78, 80 at the first and second ends 60, 62 of the plate 56. The film 84 adheres to the solar array 20 and the plate 56 with adhesive on one side of the film 84. Only using adhesive on one side of the film 84 allows the film 84 to be as clear as possible. When the film 84 as clear as possible, light and therefore radiation easily passes through the film 84 and can be absorbed by the solar array 20. Further, when the film 84 is clear, the film 84 is better able to withstand discoloration associated with UV ray affect.

The film 84 is configured to protect the solar array 20 across the area 64 defined by the solar array within the housing 54. The film 84 may be an ethylene vinyl acetate film 84. The ethylene vinyl acetate film 84 may be heat cured to laminate the plurality of solar cells 22. Laminating the plurality of solar cells 22 allows the film 84 to provide a vacuum-tight seal around the plurality of solar cells 22 to inhibit moisture from contacting the plurality of solar cells 22 as well as protecting the plurality of solar cells 22 as described above. The film 84 may be any elastomeric polymer that maintains good clarity, hot-melt adhesive and waterproof properties, and UV radiation resistance. The solar array 20 may be completely covered across the area 64 by the film 84 to provide further isolation from damage or corrosion via the film 84 and the first and second seals 78, 80 due to normal operational use of the vehicle 10.

FIG. 4 depicts a cross-sectional view of the second embodiment of the solar panel module 18. The second embodiment of the solar panel module 18 still includes the housing 54, the plate 56 and the bracket 58. Further, the second embodiment of the solar panel module 18 still uses a plurality of ribs 66 on the plate 56 over the area 64 defined by the solar array 20 to support the solar array 20 and prevents SAG within the solar panel module 18 to maximize absorption of radiation energy by the plurality of solar cells 22. Likewise, the housing 54 surrounds the area 64 and seals moisture from the solar array 20 using the first and second seals 78, 80, as described above. The solar array 20 is still adhered to the plate 56 using an electrical discharge film 23. The film 84 still covers the area 64 defined by the solar array 20 to protect and seal the solar array 20.

In the second embodiment, the solar panel module 18 further includes at least one vent 86, and adapter 88 and the cover 90. The at least one vent 86 is defined in the plate 56. The at least one vent 86 may be defined on either the first and 60 or the second end 62 of the plate 56. In at least one other embodiment, the plate 56 may define two vents 86 defined on both the first end 60 in the second and 62. The vent 86 aids to dissipate heat from the solar array 20 via the plate 56 and the plurality of ribs 66, as described above. To maintain optimal performance of the solar array 20, the vent 86 allows heat to escape from the solar panel module 18 to avoid overheating of the solar array 20. The vent 86 is defined on the plate 56 near the bracket 58 to avoid sacrificing rigidity of the plate 56 and therefore the solar panel module 18. Further, the vent 86 is defined within the housing 54 to maintain the first and second seals 78, 80 such that moisture is inhibited from contacting the solar array 20. Again, the at least one vent 86 may aid the solar array 20 and absorbing radiation and converting radiation energy to electrical energy by dissipating unnecessary heat away from the solar array 20.

The cover 90 extends across the area 64 defined by the solar array 20 to further protect and seal the solar array 20. The cover 90 may be in addition to the film 84. The cover 90 may be semi-tempered or annealed glass to provide further protection of the plurality of solar cells 22. Again, as stated above, the cover 90 needs to be clear in order to avoid distortion of the radiation energy through the cover 90 before absorption by the plurality of solar cells 22. Likewise, the cover 90 may be used on either of the first part 34, the second part 36 or both the first and second parts 34, 36 of the solar panel module 18 as described above. The cover 90 extends from the first end the 60 of the plate 56 to the second and the 62 of the plate 56 and attaches to the housing 54 at both the first and second ends 60, 62. Again, the pressure sensitive tape 82 adheres to the housing 54 and the cover 90 to provide attachment between the housing 54 and the cover. The pressure sensitive tape 82 also provides sealing of the solar panel module 18 to inhibit moisture or other corrosive fluid from contacting the solar array 20.

The adapter 88 extends between the plate 56 and the cover 90. The adapter 88 provides a bonding interface between the cover 90 and the plate 56. The adapter 88 provides an extension of the plate 56 to account for a combined thickness 92 of the solar array 20 with the film 84 up to the cover 90. Specifically, the adapter 88 defines a height 94 to attach the cover 90 to the plate 56 and avoid pressure on the solar array 20 from the cover 90. The adapter 88 does not significantly increase the size of the solar panel module 18. For example, the housing 54 may still be configured to wrap around the solar array 20 and the first and second seals 78, 80 may still be configured to attach to the first and second ends 60, 62 of the plate 56. Addition of the adapter 88, and therefore the cover 90, requires no further modification of the solar panel module 18. Adaptation of the solar panel module 18 without significant modification to the solar panel module 18 allows for the interchangeability of the embodiment shown and discussed in FIG. 3 and the embodiment shown and discussed in FIG. 4, as detailed above. Each embodiment may be used individually, or in conjunction with the other depending on the use circumstances described above.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

1. A vehicle comprising:
a roof panel defining an opening;
a support structure attached to the roof panel and disposed within the opening, the support structure including first and second sections, at least two leg portions, and a divider disposed between the leg portions and separating the first and second sections, the first section being defined between the leg portions and the divider, and the second section being defined between the leg portions and the divider disposed adjacent the first section; and
a solar panel module disposed within the first or second section, the solar panel module including a solar array adhered, via an electrical discharge film, to a plate having a plurality of ribs extending across an area of the solar array, the ribs having a V-shaped cross-section spaced throughout the area to support the solar panel module within the support structure.

2. The vehicle of claim 1 further comprising a housing attached around the solar panel module and including first and second seals disposed in a normal manner to inhibit moisture to contact the plate and solar array.

3. The vehicle of claim 1, wherein the V-shaped cross-section of the ribs is further configured to absorb heat from the solar panel module.

4. The vehicle of claim 2 further comprising a cover disposed within and underneath the housing, opposite the plate to sandwich the solar array between the cover and the plate within the housing.

5. The vehicle of claim 4 further comprising first and second brackets disposed on opposite ends of the solar panel module configured to attach the solar panel module to one of the first or second sections and the divider of the support structure.

6. The vehicle of claim 1 further comprising a windowpane disposed adjacent the solar panel module and defined in the first section of the support structure if the solar panel module is defined in the second section and defined in the second section of the support structure if the solar panel module is defined in the first section.

7. The vehicle of claim 6 further comprising a track attached to the leg portions configured to allow the windowpane to slide underneath the solar panel module.

8. A vehicle roof panel comprising:
a support structure having a first section defined by an outer periphery of the support structure; and
a solar panel module disposed within the first section, and including a solar array adhered to a plate having a plurality of ribs extending across an area of the solar array, the ribs having a V-shaped cross-section spaced throughout the first section to support the solar panel module within the support structure.

9. The vehicle roof panel of claim 8 further comprising a bracket to attach the solar panel module within the first section.

10. The vehicle roof panel of claim 8, wherein the plate further includes at least one vent configured to dissipate heat via the plate and the plurality of ribs from the solar panel module to atmosphere.

11. The vehicle roof panel of claim 8, wherein the plate is folded to form first and second layers at first and second ends of the plate.

12. The vehicle roof panel of claim 11 further comprising a housing configured to surround the solar panel module and including a first seal disposed at the first end of the plate and a second seal disposed at the second end of the plate and configured to contact the first and second layers to inhibit moisture from contacting the solar array.

13. The vehicle roof panel of claim 8, wherein the solar array is covered using ethylene vinyl acetate.

14. The vehicle roof panel of claim 8, wherein the support structure further defines a second section configured to support a pane.

15. The vehicle roof panel of claim 8, wherein the solar array is connected in series.

16. A support structure for a vehicle roof panel comprising:
a solar panel module disposed within an opening defined by an outer periphery of a support structure, the solar panel module including a first part configured to slide underneath a second part containing a solar array adhered to a plate having a plurality of ribs extending across the solar array, the ribs having a V-shaped cross-section to support the solar panel module within the second part.

17. The support structure of claim 16, wherein the first part further includes a solar array.

18. The support structure of claim 16 further comprising a cover extending over the solar panel module to shield the solar array.

19. The support structure of claim 18 further comprising an adapter disposed between the plate and the cover to provide a bond interface between the plate and the cover such that the cover does not contact the solar array.

20. The support structure of claim 19, wherein the adapter defines a height such that the height of the adapter is greater than a thickness of the solar array.
